(19) United States
(12) Patent Application Publication
(10) Pub. No.: US 2026/0364735 A1
(43) Pub. Date: Nov. 19, 2026

(54) SUBSTRATE POLISHING APPARATUS AND SUBSTRATE PROCESSING APPARATUS EQUIPPED WITH THE SAME

(71) Applicant: KCTECH CO., LTD., Gyeonggi-do (KR)

(72) Inventors: Jong Moon PARK, Gyeonggi-do (KR); Seong Hyeon PARK, Gyeonggi-do (KR)

(21) Appl. No.: 19/675,744

(22) Filed: May 13, 2026

(30) Foreign Application Priority Data
May 14, 2025 (KR) 10-2025-0062378

(51) Int. Cl. B24B 37/005; B24B 37/34; H10P 72/00; H10P 72/50

(52) U.S. Cl. CPC B24B 37/005; B24B 37/345; H10P 72/0428; H10P 72/50

(57) ABSTRACT

A substrate polishing apparatus comprises a turntable having an upper surface, on which a polishing pad is disposed, and rotates during a polishing process, a substrate transfer handler configured to supply a substrate onto the upper surface of the turntable, a substrate position detection unit configured to detect a position of the substrate when the substrate transfer handler causes the substrate to be positioned above a target seating portion of the polishing pad, and a polishing head configured such that a position of the substrate transfer handler is corrected so that the position of the substrate detected by the substrate position detection unit is a predetermined process position, the substrate transfer handler causes the substrate to be seated at the predetermined process position, then moves to a position above the substrate seated on the polishing pad, and presses the substrate downward during the polishing process for the substrate.

### CROSS-REFERENCE TO RELATED APPLICATIONS

This application claims the benefit of the Korean Patent Application No. 10-2025-0062378 filed on May 14, 2025, which is hereby incorporated by reference as if fully set forth herein.

### FIELD

The present invention relates to a substrate processing apparatus and a substrate polishing apparatus used therefor, and more specifically, to a substrate polishing apparatus that enables a double side polishing process for a large-area substrate used in a display device to be installed in a small installation area while increasing the reliability of substrate supply to a substrate processing apparatus to improve polishing quality.

### BACKGROUND

Generally, display devices widely employ glass substrates with excellent strength and transmittance, and however, as display devices have recently been aiming for slimmer designs and higher pixel counts, glass substrates corresponding thereto should be prepared.

For example, in an excimer laser annealing (ELA) process, which is one organic light-emitting diode (OLED) manufacturing process of applying a laser to amorphous silicon (a-Si) to crystallize the amorphous silicon (a-Si) into polysilicon (poly-Si), polysilicon may be crystallized so that protrusions may be formed on the surface, and the protrusions may cause mura effects, and thus a glass substrate should be polished to remove the protrusions.

A substrate processing apparatus 9 illustrated in FIG. 1 has a substrate G seated on a stage 10, and a polishing head 30 having a lower surface on which a polishing pad having a smaller area than the substrate G is disposed moves (30d) while rotating and, at the same time, a gantry 20 equipped with the polishing head 30 moves (20d) along a moving rail 22 to polish a surface of the substrate.

However, since a substrate G used in a display device is formed as a large-area substrate in the form of a rectangular or square flat plate with a side length of 500 mm or more, a problem that a process of polishing the entire surface of the substrate G while moving a small polishing head takes an excessively long time occurs. In addition, since the substrate G is polished with the polishing pad only on a part of the surface thereof, there is a problem in that the possibility of a variation in a polishing rate of the entire substrate cannot be excluded.

Recently, a substrate used in a display device has been formed with a uniform thickness overall, and thus it is necessary to polish the substrate to have a more precise flat surface. Further, the possibility of applying a large-area glass substrate is being raised even in the semiconductor manufacturing process, and a substrate used in the manufacture of a semiconductor package also needs to be polished to a precise thickness as large-area substrates. In particular, when a substrate containing both copper and titanium is to be polished, precise polishing is very difficult due to a difference in its hardness, and thus it is necessary for resolving this issue.

At the same time, an apparatus for polishing a large-area substrate used in a display device requires a very large installation area, and thus there is an urgent necessity for a method of minimizing an installation area while efficiently performing a double side polishing process of a substrate.

The above-described configuration is for comparison with the present invention and does not imply technology known prior to the filing date of the present invention.

### SUMMARY

The present invention aims to polish both surfaces of a large-area substrate used in the manufacture of a display device or a semiconductor package to minimize variations in the polishing amount.

In addition, the present invention aims to improve the positional precision of a polishing head pressing a substrate by capturing a position of the substrate and placing the substrate at a predetermined position during a process of placing the substrate on a polishing pad in contact with an entire surface of the substrate.

Further, the present invention aims to polish both surfaces of a large-area substrate in a minimal installation area or to polish the large-area substrate with materials having different hardnesses in different ways to reach a target thickness.

To achieve the objects of the present invention described above, a substrate polishing apparatus including a turntable which has an upper surface, on which a polishing pad is disposed, and rotates during a polishing process, a substrate transfer handler configured to supply a substrate onto the upper surface of the turntable, a substrate position detection unit configured to detect a position of the substrate when the substrate transfer handler causes the substrate to be positioned above a target seating portion of the polishing pad, and a polishing head configured such that a position of the substrate transfer handler is corrected so that the position of the substrate detected by the substrate position detection unit is a predetermined process position, the substrate transfer handler causes the substrate to be seated at the predetermined process position of the polishing pad, then moves to a position above the substrate seated on the polishing pad, and presses the substrate downward during the polishing process for the substrate is provided.

In addition, the present invention provides a substrate processing apparatus, in which a substrate polishing process is performed on a substrate, including a substrate supply unit configured to supply a substrate on which a polishing process is to be performed, a substrate transfer handler on which the substrate supplied from the substrate supply unit is seated and which reciprocates along a substrate supply path disposed along a linear shape to supply the substrate, a substrate supply handler configured to supply the substrate from the substrate supply unit along the substrate supply path, a first processing apparatus which is disposed on one side of the substrate supply path and performs a first processing process on the substrate supplied from the substrate transfer handler, and a second processing apparatus which is disposed adjacent to the first processing apparatus on one side of the substrate supply path and performs a second processing process on the substrate on which the first processing process has been performed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a view illustrating a configuration of a conventional substrate processing apparatus;

FIG. 2 is a plan view illustrating a configuration of a substrate processing apparatus according to a first embodiment of the present invention;

FIGS. 3A, 3B, 3C and 3D are plan views illustrating a configuration of a first processing apparatus of FIG. 2 according to a process sequence of supplying a substrate and performing a polishing process;

FIG. 4A is a view illustrating a configuration of a substrate aligned with a polishing head;

FIG. 4B is a perspective view illustrating a configuration in which a polishing process is performed on a substrate while pressed by a polishing head;

FIG. 5 is a half-sectional view illustrating a configuration of a polishing head of FIG. 3A;

FIG. 6 is an enlarged view of portion “A” of FIG. 5;

FIG. 7 is a bottom view of FIG. 5;

FIG. 8 is an enlarged view illustrating a configuration of a cleaning unit of FIG. 2; and

FIG. 9 is a plan view illustrating a configuration of a substrate processing apparatus according to a second embodiment of the present invention.

### DETAILED DESCRIPTION

Hereinafter, exemplary embodiments of the present invention will be described in detail with reference to the accompanying drawings, but the present invention is not limited or restricted by the embodiments. For reference, the same numbers refer to substantially the same components throughout this specification, and under these rules, descriptions may be made by citing content described in other drawings, and content that is deemed obvious to those skilled in the art or is repetitive may be omitted.

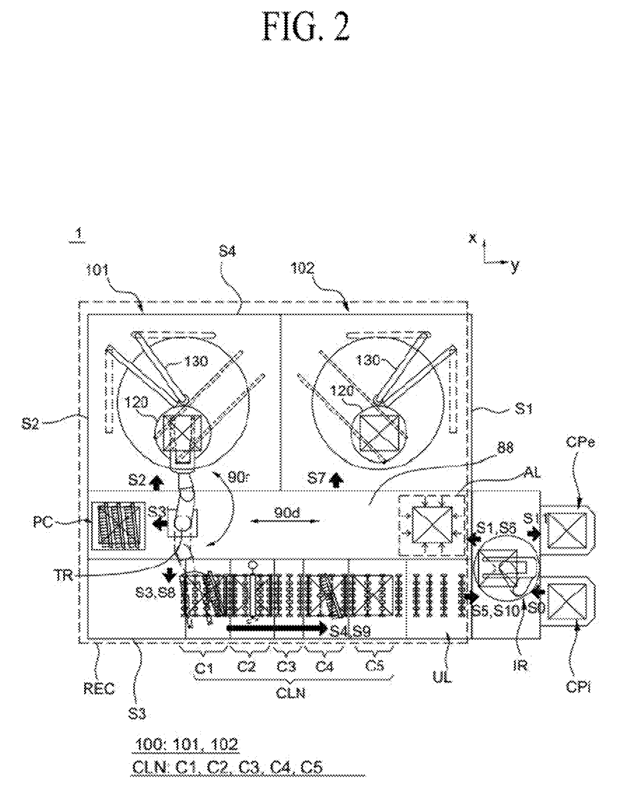

As illustrated in FIG. 2, a substrate processing apparatus 1 according to a first embodiment of the present invention is installed to be compactly disposed in an installation area REC of a substantially rectangular shape to increase the polishing efficiency of a substrate G and includes a substrate supply unit Cpi which is disposed outside one side S1 of the installation area REC to load the substrate G and supplies a substrate to be polished, a substrate supply handler IR which is disposed between the substrate supply unit Cpi and the one side S1 to supply the substrate G from the substrate supply unit CPi to an alignment unit AL of a substrate supply path 88, the alignment unit AL which is positioned at one end portion of the substrate supply path, through which the substrate G is supplied by the substrate transfer handler IR, and which aligns the position and attitude of the supplied substrate G, a substrate transfer handler TR which loads the substrate G aligned in the alignment unit AL and reciprocates the substrate supply path 88 disposed to connect the one side S1 and another side S2 along a linear shape in an ±x-axis direction to supply the substrate G to processing apparatuses 101 and 102 or a cleaning unit CLN, a first processing apparatus 101 which is disposed adjacent to the substrate supply path 88 in a ±y-axis direction and performs a first processing process on the substrate G supplied from the substrate transfer handler TR, a second processing apparatus 102 which is disposed adjacent to the substrate supply path 88 together with the first processing apparatus 101 and performs a second processing process on the substrate G on which the first processing process has been performed, a preliminary cleaning unit PC which is disposed at another side end portion of the substrate supply path 88 to preliminarily remove foreign substances remaining on the substrate G before performing a subsequent processing process after the processing process has been performed in the processing apparatuses 101 and 102, and the cleaning unit CLN which includes a plurality of cleaning chambers C1, C2, ..., and C5 arranged in a row along the substrate supply path 88 to face the processing apparatuses 101 and 102 with respect to the substrate supply path 88 to clean and dry the substrate G.

Here, the substrate G is a large-area substrate with a width and a length, each of which is about 500 mm or more, and a substrate used in the manufacture of a glass display device or a semiconductor package may be applied. However, the present invention is not limited thereto, and a substrate with a width and a length, each of which is 100 mm or more, may also be applied. The substrate G may be formed of a glass material in a quadrangular shape, may be formed of other materials, or may be a substrate having both a copper layer and a titanium layer.

A substrate G on which a polishing process is to be performed is loaded on the substrate supply unit Cpi and remains in a waiting state. A single substrate G may be waiting in the substrate supply unit Cpi or a plurality of substrates G may be waiting. In addition, when a new substrate G is to be provided into the polishing process for the substrate processing apparatus 1, a single substrate G is supplied from the substrate supply unit Cpi to the alignment unit AL of the substrate supply path 88 using the substrate supply handler IR (S0 and S1).

The substrate supply handler IR is used to move a single substrate from the substrate supply unit Cpi to the alignment unit AL or move a cleaned substrate G from an unloading unit UL positioned at an outermost end portion in a flow direction of the cleaning unit CLN to a substrate discharge unit CPe or the alignment unit AL (S4 and S9). A plurality of suction ports may be provided to adsorb and grip the substrate G so that the substrate G does not fall while gripped.

The alignment unit AL aligns a position and attitude (rotation angle) of the substrate G to a predetermined state by pushing an edge of the substrate while supporting a lower surface of the substrate with a roller, a support, etc., so that a portion of the lower surface of the substrate G or the entire lower surface of the substrate G is lifted.

For example, the alignment unit AL may mount the substrate G such that at least a portion of the lower surface of the substrate G is separated from a bottom surface thereof, and the substrate transfer handler TR may grip the substrate G by adsorbing and lifting the lower surface of the substrate G using a fork. Alternatively, the alignment unit AL may include a plurality of rollers that support the lower surface of the substrate and may be formed to rotate the rollers toward the substrate transfer handler TR, transfer the substrate G, and place the substrate G on the substrate transfer handler TR.

The substrate transfer handler TR is installed to reciprocate (90d) along the substrate supply path 88 disposed on the center of the installation area REC along a linear shape in the ±x-axis direction. The substrate transfer handler TR may grip the substrate G by inserting the fork into a gap under the lower surface of the substrate lifted from the bottom surface in the alignment unit AL, applying a suction pressure to a suction hole of the fork to fix the substrate G, and lifting the lower surface of the substrate G. In addition, the substrate transfer handler TR is installed to rotate the substrate G 360 degrees (90r) so as to supply the substrate G to the first processing apparatus 101, the second processing apparatus 102, and an inlet chamber C1 of the cleaning unit CLN. At the same time, the substrate transfer handler TR is formed to flip the substrate G by rotating the gripped portion 180 degrees while gripping the substrate G.

That is, the substrate transfer handler TR is formed to reciprocate along the substrate supply path 88 to supply the substrate to the processing apparatuses 101 and 102 and the cleaning unit CLN or to fetch the substrate from the processing apparatuses 101 and 102, and to flip the substrate G 180 degrees as necessary. Preferably, the substrate transfer handler TR may include a plurality of suction units that apply a suction pressure and may be formed such that the suction units come into contact with an inactive region of the substrate G that is not used in the manufacture of a display device or a semiconductor package to adsorb or grip the substrate G.

As necessary, a mist nozzle that supplies liquid in the form of a mist may be provided in the substrate transfer handler TR so that liquid (e.g., pure water) may be applied in the form of a mist to an upper surface of the substrate G supplied to each processing apparatus 100 (101 and 102), and the substrate G may be supplied with the liquid attached in the form of a mist to the upper surface of the substrate G. Through this, a small amount of liquid is interposed between a membrane 124 of a polishing head 120 and the substrate G so that the membrane 124 and the substrate G may be attached by a surface tension of the liquid and may move integrally.

Although the substrate transfer handler illustrated in the drawing is illustrated as one substrate transfer handler, a plurality of substrate transfer handlers may be formed to move in one column or in each of a plurality of columns along the substrate supply path 88.

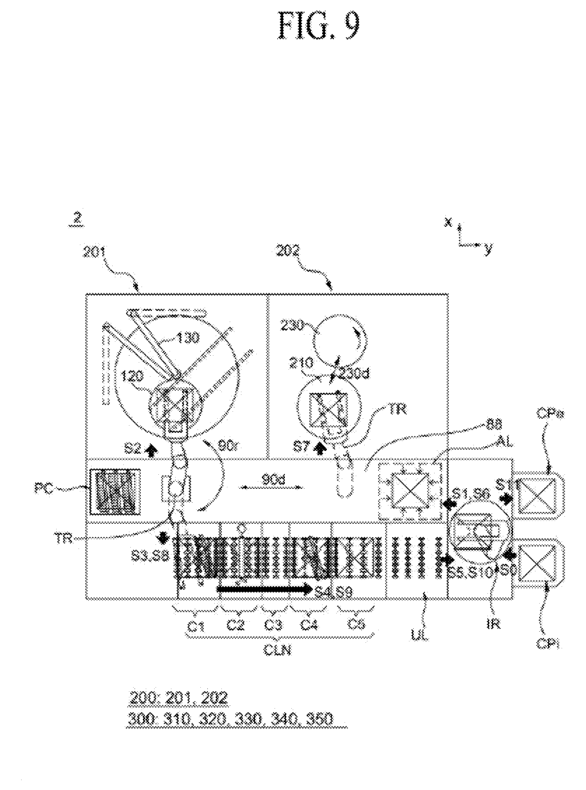

The processing apparatus 101 includes the first processing apparatus 101 and the second processing apparatus 102 that are disposed side by side adjacent to the substrate supply path 88. As illustrated in FIG. 2, the processing apparatuses 101 and 102 may be formed to polish a first surface and a second surface of the large-area substrate G, respectively, and as illustrated in FIG. 9, any one of the processing apparatuses 101 and 102 may be formed to polish a specific material of the large-area substrate G, and the other may be formed to polish another specific material of the large-area substrate G.

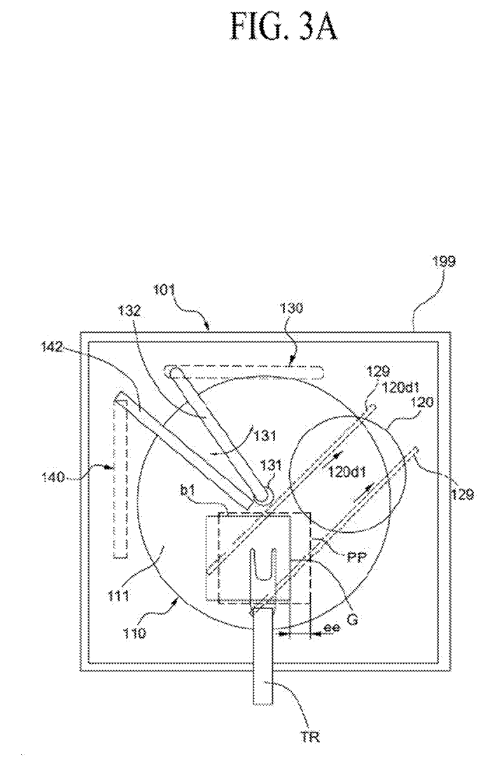

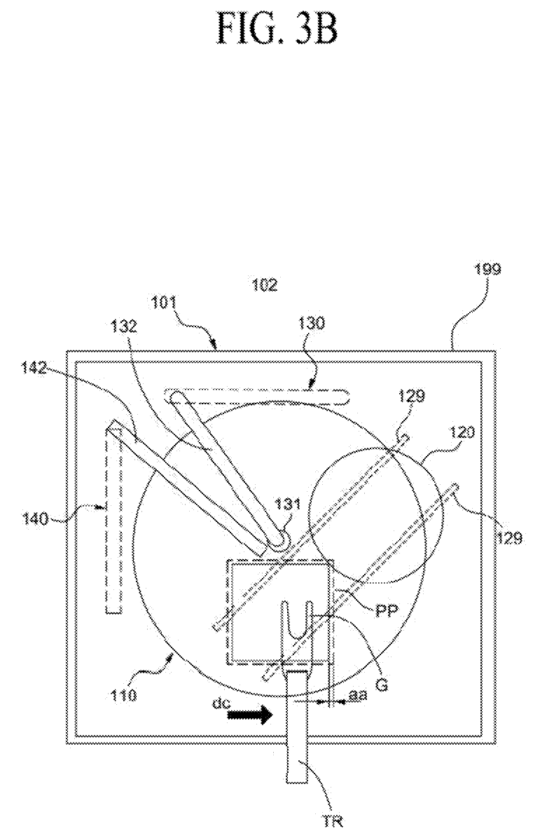

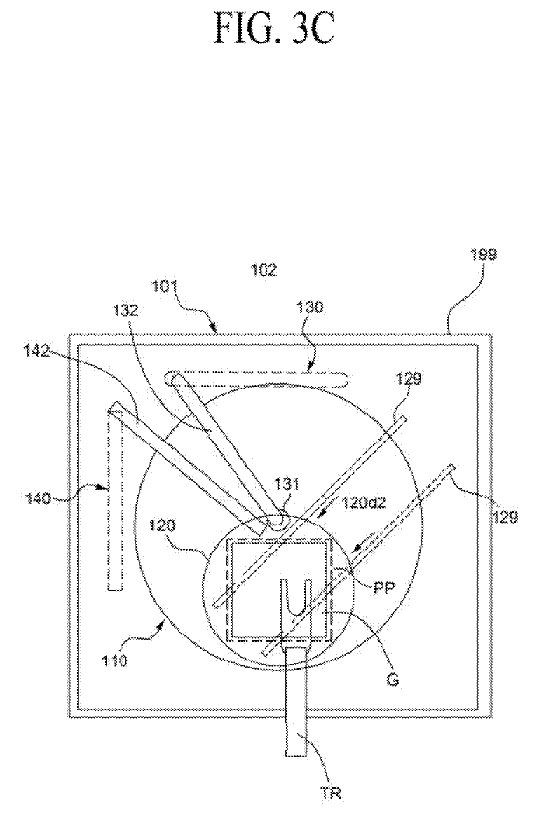

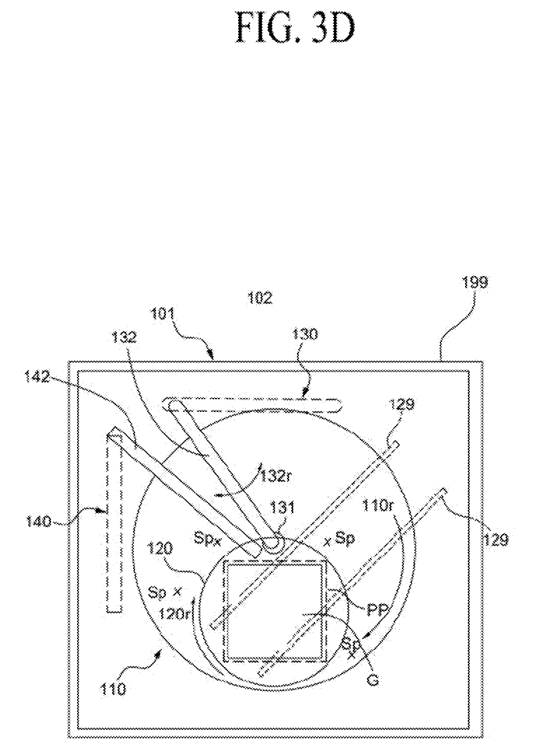

First, referring to the configuration illustrated in FIG. 2, as illustrated in FIGS. 3A - 3D, polishing is performed on the substrate G in a state in which the entire surface of the substrate G is in close contact with a polishing pad 111 that is wider than the substrate G. Each processing apparatus 100 (101 and 102) is maintained in a state of being sealed from the outside by an inner wall 199 or the like so that a polishing liquid or the like inside does not leak to the outside during the polishing process.

The processing apparatus 100 includes the first processing apparatus 101 which is disposed on one side of the substrate supply path 88 and performs a first polishing process for polishing the first surface of the substrate G supplied from the substrate transfer handler TR, and a second processing apparatus 102 which is disposed side by side adjacent to the first processing apparatus 101 on one side of the substrate supply path 88 and performs a second polishing process for polishing the second surface of the substrate G supplied from the substrate transfer handler TR.

According to an exemplary embodiment of the present invention, the first processing apparatus 101 and the second processing apparatus 102 are formed to be the same as illustrated in the drawing. However, the present invention is not limited thereto, and as illustrated in FIG. 9, the first processing apparatus 201 and the second processing apparatus 202 may be formed in different forms from each other.

A detailed configuration of each processing apparatus 100 will be described below with a focus on the first processing apparatus 101. As illustrated in FIG. 3A, the first processing apparatus 101 includes a turntable 110 which rotates with the polishing pad 111 disposed on an upper surface thereof, with which the first surface of the substrate G comes into contact, the polishing head 120 which rotates while pressing the substrate G against the polishing pad 111 with the substrate G positioned thereunder, a conditioner 130 which modifies a state of a surface of the polishing pad 111 during the polishing process for the substrate G, and a slurry supply unit 140 which supplies a slurry between the substrate G and the polishing pad 111.

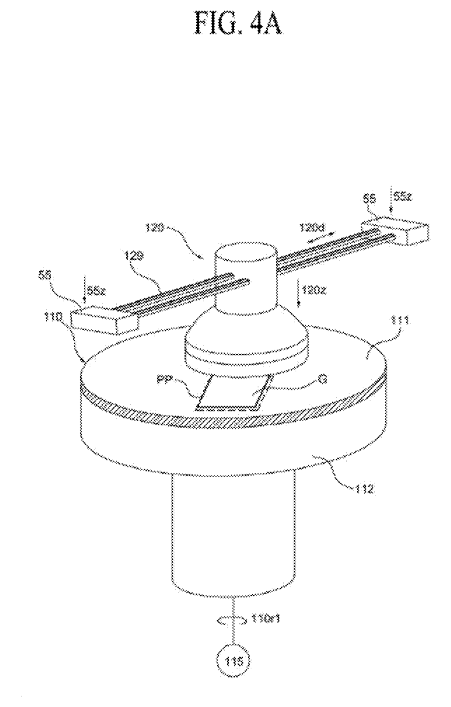

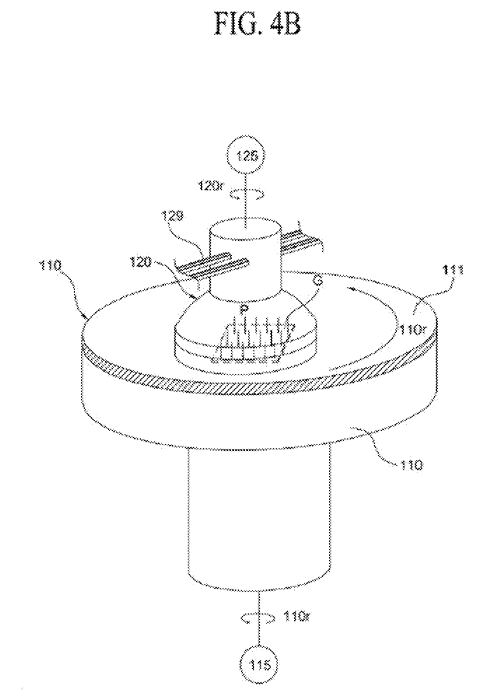

Here, as illustrated in FIG. 4A, the turntable 110 includes a rotating body 112 which is rotatable (110r) by a turntable driving unit 115, and the polishing pad 111 which is disposed on an upper surface of the turntable 110 and comes into frictional contact with the substrate G.

The polishing head 120 is installed to reciprocate (120d) between an upper position and a retracted position of a predetermined process position PP on which the substrate G is seated on the polishing pad 111, at the same time, is installed to move up and down (120z) between a position at which the substrate G seated at the process position PP is pressed and an upper position thereof, and at the same time, is formed to be rotated (120r) by a head driving unit 125.

To this end, as illustrated in FIG. 4A, a moving rail 129 is provided to guide the reciprocating movement of the polishing head 120 to the upper position and the retracted position of the planned process position PP. In addition, the polishing head 120 is moved up and down (120z) by the up and down movement (55z) of the support 55 of each of two end portions of the moving rail 129. However, the present invention is not limited thereto, and various units for moving up and down (120z) between the upper position of the polishing head 120 and the planned process position PP of the substrate and at the same time, moving back and forth (120d) between the upper position and the retracted position are included as parts of the present invention.

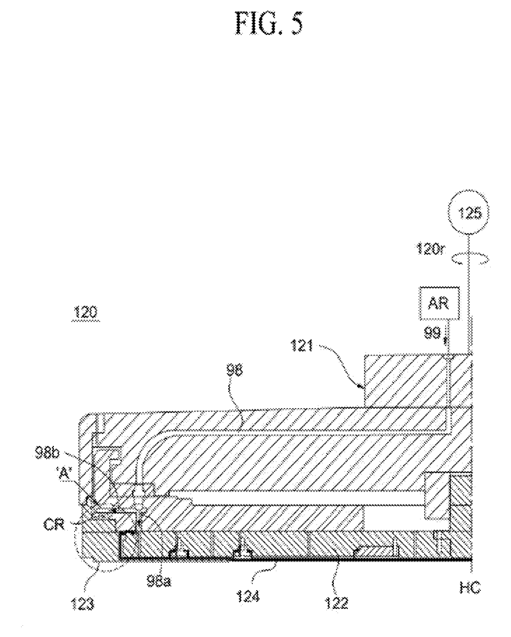

As illustrated in FIG. 5, the polishing head 120 includes a head body 121 that is rotated by the head driving unit 125, a base member 122 that rotates together with the head body 121, a membrane 124 that is fixed to the base member 122 and adheres to the upper surface of the substrate G to press the substrate G during the polishing process, and a retainer 123 that is fixed to the head body 121 and accommodates the substrate G in an accommodating through opening 123x according to the quadrangular shape of the substrate G.

Here, the head body 121 is connected to the head driving unit 125 through a connecting shaft to receive a rotational driving force, is connected to the base member 122 by a connecting pin to transmit the rotational driving force to the base member 122 and rotates together with the base member 122. The retainer 123 is coupled to a main body 121a of the head body 121 and rotates integrally with the head body 121.

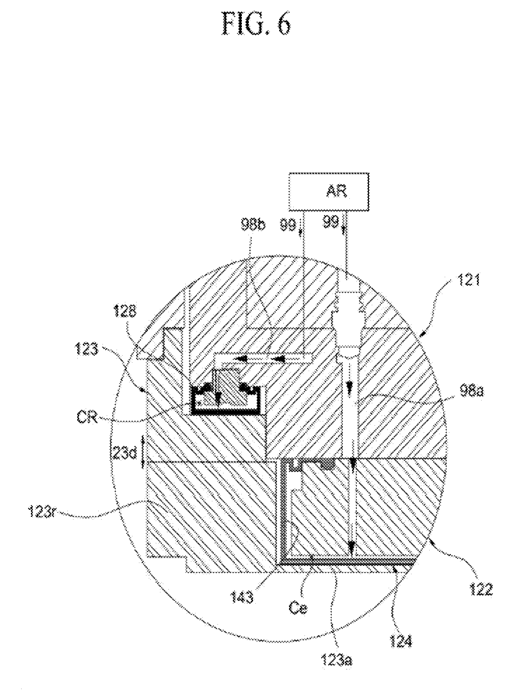

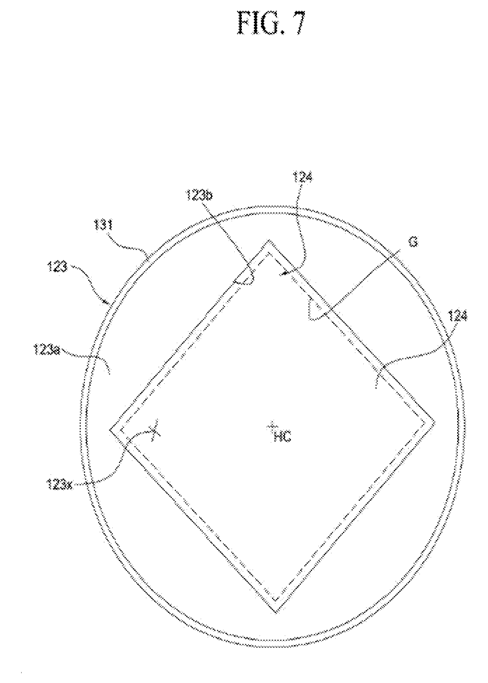

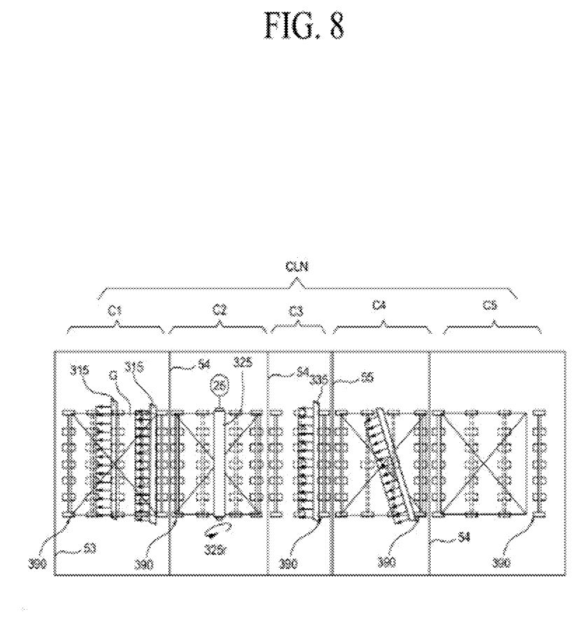

The retainer 123 is coupled to the main body 121a of the head body 121 and rotates integrally with the head body 121 while maintaining a state in which a bottom surface thereof is in contact with the polishing pad 111 during the polishing process. Here, the substrate G has a non-circular shape (e.g., a polygonal shape), and the polishing head 120 is a rotating body and has a circular cross-sectional shape, and thus, as illustrated in FIGS. 6 and 7, an upper portion 123r of the retainer 123 is formed in a circular ring shape, a lower portion 123a is formed in a form disposed under a bottom plate of the circular membrane 124, and the accommodating through opening 123x is formed in the central portion along the shape of the substrate G. The upper portion 123r of the retainer 123 is formed of a hard metal material, and the lower portion 123a of the retainer 123 is formed of a material that is worn down upon contact with the polishing pad 111. Through this, the quadrangular-shaped substrate G is accommodated in the accommodating through opening 123x of the retainer 123 and rotates together with the rotation of the polishing head 120 and, at the same time, the substrate G is prevented from moving out of the retainer 123 due to a centrifugal force during the polishing process. The lower portion 123a of the retainer 123 is formed of a material (e.g., resin or plastic material such as PEEK) with lower hardness than the polishing pad 111 so as not to affect the wear of the polishing pad 111 during the polishing process, thereby maintaining the consistent polishing quality of the substrate G. The retainer 123 may be formed entirely of the same material, but the lower portion may be formed of a material with lower hardness than the polishing pad 111, and the upper portion 123r may be formed of a metal material to ensure bonding stability with the head body 121.

The membrane 124 is formed of a flexible material capable of bending and stretching under an external force and is coupled to the base member 122 to form a pressure chamber Ce sealed from the outside in a space between the membrane 124 and the base member 122. For example, the membrane 124 may be formed of polyurethane or a similar material. A pressure in the pressure chamber Ce is adjusted by supplying a pneumatic pressure 99 from a pressure adjustment unit AR through an air passage 98a. Accordingly, by adjusting the pressure in the pressure chamber Ce, the pressure applied to the substrate G against the polishing pad 111 during the polishing process for the substrate G may be adjusted. Accordingly, a mechanical polishing rate of the substrate G is adjusted.

Meanwhile, as the lower portion 123a of the retainer 123 is formed to extend inwardly toward a lower side of a bottom plate of the membrane, the lower portion 123a of the retainer 123 presses the polishing pad 111 downward by the pressure chamber Ce formed on an upper side of the membrane. A ring-shaped retainer chamber CR is provided on an upper side of the retainer 123, and the pressure in the retainer chamber CR is adjusted to be a positive or negative pressure by the pneumatic pressure 99 supplied from the pressure adjustment unit AR through an air passage 98b, thereby moving the retainer 123 in the up and down direction (23d). During the polishing process, the pressure in the retainer chamber CR is adjusted to a negative pressure, thereby lifting the retainer 123, which is pressed downward by the pressure chamber Ce formed by the membrane 124, upward to offset a portion of the force with which the retainer presses the polishing pad, thereby preventing the substrate G from moving out of the polishing head by the retainer, while also preventing the polishing amount at the edge of the substrate G from becoming uneven compared to the center as the lower portion 123a of the retainer presses the polishing pad 111 with an excessive force.

The conditioner 130 is equipped with an arm 132 that rotates relative to a column positioned outside the turntable 110 and a conditioning disc 131 that is moved by the rotational movement 132r of the arm 132 and modifies the polishing pad 111 by coming into contact with the polishing pad 111 while the rotational movement 132r and self-rotation are simultaneously performed during the polishing process or during a time between polishing processes.

The slurry supply unit 140 may supply a slurry to the rotation center of the polishing pad 111 or a portion adjacent to the substrate G during the polishing process, thereby enabling chemical polishing of the substrate G.

The substrate G used in the polishing process is a transparent substrate used in a display device, and a large-area substrate with a side length of 500 mm or more is used. In addition, a thickness of the substrate G was used to be 1.1 mm or less up to the 4^{th} generation substrate, but for recent 11^{th} generation and later substrates, a substrate G with a thickness of 0.5 mm or less is used. Accordingly, since the large-area substrate is easily subjected to bending deformation, it is difficult to mount the large-area substrate on the polishing head.

Therefore, as illustrated in FIG. 3A, the substrate G is seated in a predetermined attitude at a predetermined process position PP with respect to the rotation center of the turntable 110 by the substrate transfer handler TR. For example, one side b1 of the substrate G may be disposed parallel to a rotational tangential direction toward the rotation center of the polishing pad 111, and the center of the substrate G may be aligned with the rotation center of the polishing pad 111 and the center of a radius end, and the position may be set as the predetermined process position PP. Here, the predetermined process position PP does not refer to a specific position relative to the polishing pad 111, but rather to a coordinate position on the polishing pad 111 spaced apart by a predetermined distance relative to the polishing head 120.

In this case, before the substrate transfer handler TR places the substrate G at the predetermined process position PP, a substrate position detection unit, such as a camera or optical sensor positioned above the turntable 110, detects whether the position of the substrate is the predetermined process position PP. Here, various sensors capable of position detection may be applied to the detection unit, and for example, a laser displacement sensor, a line scan camera, etc., capable of edge detection may be applied. As illustrated in FIG. 3A, when it is detected that the substrate G has a length and angle deviation from the predetermined process position PP by a length indicated by a reference numeral “ee,” as illustrated in FIG. 3B, the substrate transfer handler TR moves (dc) along an x-axis and a y-axis by the length indicated by “ee” or rotates to correct the position so as to align with the predetermined process position PP of the substrate.

Thereafter, the substrate transfer handler TR places the substrate G at the predetermined process position PP of the polishing pad 111. In this case, as illustrated in FIG. 3A, the polishing head 120 is maintained in a retracted position (120d1) away from the upper position of the process position PP along the moving rail 129. Through this, interference with the polishing head 120 may be avoided during the process of placing the large-area substrate G at the process position PP using the substrate transfer handler TR. Here, the path along which the polishing head 120 moves to avoid interference may be determined in various ways. For example, as illustrated in FIG. 3A, the moving rail 129 along which the polishing head 120 moves may be disposed in a diagonal direction and formed to extend in a direction excluding a vertical direction (y-axis direction) relative to the drawing.

Thereafter, as illustrated in FIG. 3C, the polishing head 120 moves (120d2) to an upper side of the process position PP of the substrate G, and as illustrated in FIG. 4A, the polishing head 120 moves downward (120z) so that the substrate G is accommodated in the quadrangular-shaped accommodating through opening 123x of the retainer 123 of the polishing head 120.

Thereafter, as illustrated in FIGS. 3D and 4B, a pneumatic pressure is transmitted to the pressure chamber Ce formed by the membrane 124 of the polishing head 120, and the polishing head 120 applies a pressure P to the substrate G so that the substrate G comes into close contact with the polishing pad 111. At the same time, the turntable 110 rotates (110r) and the polishing head 120 also rotates (120r) in the same direction as the turntable 110, and a slurry is supplied from the slurry supply unit 140 to the rotation center region of the polishing pad 111 so that chemical polishing and mechanical polishing are performed on the first surface of the substrate G.

In this case, as illustrated in FIG. 3D, a plurality of perimeter positions Sp outside the polishing head 120 are equipped with a displacement detection sensor that detects the slip-out displacement of the substrate G from the upper side by means of an optical sensor or the like. Through this, the displacement to the outside of the polishing head 120 may be detected by the displacement detection sensor even when the retainer 123 presses the polishing pad during the polishing process for the substrate G.

In addition, in order to prevent the substrate G from being polished to a portion in which a wave pattern appears during the polishing process, an oscillation motion in which the polishing head 120 or the turntable 110 moves back and forth over a predetermined short distance (e.g., a distance of 1/10000 to 1/100 times the side length of the substrate G) is performed during the polishing process. In this case, the polishing head 120 performs an oscillation movement along the moving rail 129 , thereby obtaining an effect of suppressing the oscillation that may occur in the polishing head 120 due to friction with the polishing pad during the oscillation motion of the polishing head 120.

By undergoing such a process, when performing the process of pressing the polishing head 120 against the large-area substrate G seated on the turn table 110, the polishing process may be performed while efficiently fixing the substrate to the polishing head and rotating the substrate, while minimizing the possibility of damage to the substrate.

According to an exemplary embodiment of the present invention, the substrate G may be supplied to the turntable 110 in a state in which pure water (DIW) is sprayed onto and adhered to the upper surface thereof. Through this, the polishing head 120 moves downward so that the upper surface of the substrate G comes into contact with a bottom surface of the membrane 124, and the upper surface of the substrate G may come into close contact with the bottom surface of the membrane 124 by a surface tension of the pure water.

Thereafter, in a state in which the upper surface of the substrate G comes into close contact with the bottom surface of the membrane 124, the pneumatic pressure 99 is supplied from the pressure adjustment unit AR to the pressure chamber Ce to adjust the pressure in the pressure chamber Ce to a pressure higher than atmospheric pressure. Then, the pressure P with which the substrate G is pressed downward is applied by the expansion of the pressure chamber Ce, and thus the substrate G may be pressed to come into close contact with the polishing pad 111.

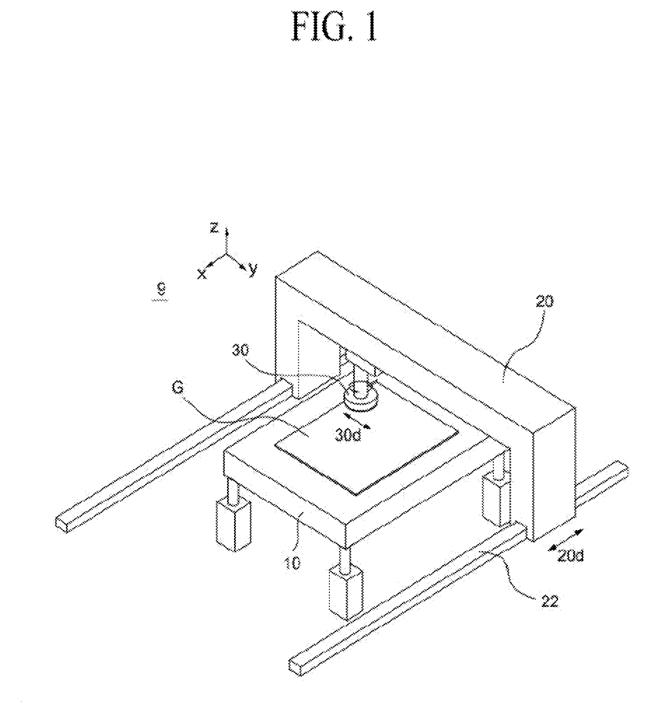

At the same time, the turntable driving unit 115 rotates (110r) the turntable 110, and the head driving unit 125 rotates (120r) the polishing head 120. In this case, the turntable 110 and the polishing head 120 rotate in the same direction (e.g., clockwise or counterclockwise). Through this, since the polishing process is performed in a state in the entire surface of the substrate G is in contact with the polishing pad 111, a higher polishing quality may be obtained as compared to the conventional configuration (see FIG. 1) in which the polishing process is performed while moving with the polishing pad 111 in contact with only a portion of the surface of the substrate G.

Further, by configuring the polishing head 120 so that the large-area substrate G with a side length of 500 mm or more is not seated on the polishing head 120 but is seated on the polishing pad 111 and the polishing head 120 moves downward to press the substrate G against the polishing pad, an advantageous effect in that the substrate G may be positioned between the polishing head 120 and the polishing pad 111 to perform the polishing process without damaging the large-area substrate G may be obtained.

When the polishing process for the substrate G is completed, the polishing head 120 moves upward and increases the pressure in the pressure chamber Ce, causing a deformation in which the bottom surface of the membrane 124 becomes convex downward, thereby overcoming the surface tension caused by the liquid interposed between the membrane 124 and the upper surface of the substrate G and separating the substrate G from the membrane 124. Thereafter, the substrate transfer handler TR adsorbs the substrate G and transfers the substrate G from the turntable 110 to a subsequent process. That is, the position at which the substrate is seated on the polishing pad 111, the position at which the polishing process is performed on the substrate G, and the position at which the substrate G is separated from the polishing pad and transferred to a subsequent process after the polishing process are all performed at a single process position PP.

When the polishing process is completed, the polishing head 120 moves upward from the process position PP to the upper position and then moves to the retracted position along the moving rail 129.

The preliminary cleaning unit PC is disposed to face the first processing apparatus 101 and disposed at an end of the substrate supply path 88 in a forward and backward direction (±x-axis direction). Accordingly, when the first polishing process for the first surface of the substrate G is completed in the first processing apparatus 101, the substrate transfer handler TR grips the substrate G and moves the substrate G to the preliminary cleaning unit PC or the cleaning unit CLN (S3 or S3’).

A waiting time of the substrate G in the preliminary cleaning unit PC is set a time until the second polishing process for another substrate is completed in the second processing apparatus 102 and the substrate G for which the first polishing process is completed in the first processing apparatus 101 may be provided into the second processing apparatus 102. This is because a polishing time of the first surface in the first processing apparatus 101 and a polishing time of the second surface in the second processing apparatus 102 may be set differently from each other.

In this way, the substrate G for which the first polishing process is completed in the first processing apparatus 101 may be seated in the preliminary cleaning unit PC, and thus a new substrate may be supplied to the first processing apparatus 101 to perform the first polishing process as soon as the first polishing process is completed in the first processing apparatus 101. Similarly, as soon as the substrate G for which the second polishing process is completed in the second processing apparatus 102 is unloaded, the substrate waiting in the preliminary cleaning unit PC may be immediately provided into the first processing apparatus 102. Therefore, the first polishing process may be consecutively performed on substrates in the first processing apparatus 101, and at the same time, the second polishing process may be consecutively performed on the substrates in the second processing apparatus 102, and thus an effect of increasing the processing efficiency of the substrates per unit time may be obtained.

Here, the preliminary cleaning unit PC may be formed to support downward while in contact with an inactive region of the substrate G. Similar to a sidewall 199 of the processing apparatuses 101 and 102, the preliminary cleaning unit PC is formed in a sealed state from the outside, and a cleaning solution sprayer that sprays a cleaning solution at a high pressure onto the first surface of the substrate G waiting in the preliminary cleaning unit PC may be provided. Through this, by performing a non-contact preliminary cleaning process on the first surface of the substrate G while the first polishing process is performed in the first processing apparatus 101, thereby removing large sludge, even when not completely, attached to the first surface during the chemical mechanical polishing process in the first processing apparatus 101, and reducing the problem of substrate defects caused by the sludge adhesion.

The substrate G on which cleaning of the first surface is performed in the atmosphere in the preliminary cleaning unit PC is transferred to the second processing apparatus 102 by the substrate transfer handler TR (S7), and is seated at a position flipped 180 degrees relative to its position in the first processing apparatus 101 so that the second surface of the substrate G faces upward, and the second polishing process is performed on the second surface.

Meanwhile, the substrate G in which the first polishing process for the first surface is completed may be transferred to the cleaning unit CLN by the substrate transfer handler TR. The cleaning unit CLN cleans the substrate G in which the first surface has been polished by the first processing apparatus 101, as illustrated in FIG. 7.

The cleaning unit CLN is adjacent to the preliminary cleaning unit PC, and a plurality of cleaning chambers C1, C2, ..., and C5 are arranged along a linear shape parallel to the substrate supply path 88. Here, the cleaning chamber includes a non-contact rinsing chamber C1 that rinses the surface of the substrate after the first polishing process is completed by spraying rinse water at a high pressure from a rinsing water spray nozzle 315 to rinse in a non-contact manner, a brush cleaning chamber C2 in which a brush cleaning unit 320 for cleaning both surfaces of the substrate G with a brush 325 is disposed, a second rinsing chamber C3 in which a rinsing unit 335 is disposed by additionally spraying a rinse solution onto both surfaces of the substrate G, a drying chamber C4 that sprays air in a line-like oblique direction onto both surfaces of the substrate G to push out and dry the liquid remaining on the surface of the substrate G, and a thermal drying chamber C5 that dries the liquid by increasing the temperature inside the chamber to a high temperature.

Since the substrate G is subjected to various cleaning, rinsing, and drying processes in the plurality of cleaning chambers, a transfer roller 390 that transfers the substrate G across these sections is provided. The transfer roller 390 is formed to transfer the substrate G at a constant speed across the entire section of the cleaning unit CLN while undergoing non-contact cleaning, brush cleaning, drying, and rinsing processes. However, the present invention is not limited thereto, and the transfer speed by the transfer roller 390 may be controlled for each chamber and thus may be controlled to temporarily stop for the cleaning process in some or more cleaning chambers.

First, as illustrated above, in the non-contact rinsing chamber C1, foreign substances remaining on the substrate G is removed first by spraying a rinsing solution at a high pressure from a rinsing solution supply nozzle 315 onto the surface of the substrate G while transferring the substrate G to the transfer roller 390. In this case, since the first surface of the substrate G has been polished in the first processing apparatus 101, sludge, which is a mixture of a slurry and liquid, remains on the first surface of the substrate G. Therefore, the sludge is removed from the first surface by the rinsing solution sprayed from the rinsing solution supply nozzle 315.

In this case, the rinsing solution supply nozzle 315 may be formed to spray a cleaning solution at a high pressure in the form of a slit nozzle so that a uniform cleaning force is applied over the entire width of the substrate. Alternatively, the rinsing solution supply nozzle 315 is provided as a plurality of rinsing solution supply nozzles 315 in the left and right direction (±y-axis direction) and may be formed to spray the cleaning solution at the high pressure onto the surface of the substrate G being transferred by the transfer roller 390. Through this, coarse foreign substances and sludge remaining on the first surface and the second surface of the substrate G may be removed while undergoing the first polishing process and the second polishing process.

In addition, in the brush cleaning chamber C2, a pair of roller-shaped brushes 325, which are made of a material similar to a sponge (e.g., polyvinyl alcohol) with protrusions formed on their outer surface, in contact with both surfaces of the substrate G are rotated in a direction opposite to the transfer direction 390 of the substrate G, thereby removing all the sludge and other foreign substances remaining on the substrate G by means of frictional force between the brushes 325 and the substrate G. In this case, in order to increase the cleaning efficiency of the brushes, a detergent in liquid or powder form is supplied from a detergent supply unit to completely remove foreign substances remaining on the substrate G.

In addition, in the second rinsing chamber C3, a rinsing solution at a high pressure from the rinsing water spray nozzle 335 is sprayed onto both surfaces of the substrate G being transferred by the transfer roller 390, thereby rinsing the cleaning liquid on the surface of the substrate G with rinsing water. Pure water (DI Water) may be selected as the rinsing water.

In addition, in the drying chamber C4, moisture remaining on the substrate is removed by obliquely spraying high pressure air along a linear shape onto both surfaces of the substrate G while transferring the substrate G to the transfer roller 390. The drying unit 340 obliquely sprays dry air in the form of an air knife. In this case, a flow direction of the dry air is set to be a direction opposite to the transfer direction of the substrate G by the transfer roller 390. Through this, the liquid remaining on the surface of the substrate G is pushed backward along the flow direction due to the dry air blowing at an angle in the direction opposite to the transfer direction of the substrate G, and the surface of the substrate G that is touched by the air knife-shaped air is dried. In this case, by obliquely placing the extension direction of the air knife at an angle with respect to the substrate G, the liquid is pushed toward one rear corner of the substrate G instead of being pushed toward the rear edge of the substrate G, thereby minimizing the amount of liquid remaining on the substrate G in the form of liquid droplets near the corner of the substrate G.

In addition, in the thermal drying chamber C5, a small amount of moisture remaining on the substrate is dried by heat.

Meanwhile, a passage through which the substrate G passes is formed between these chambers C1 to C3, and a partition 54 is formed so that the passage is always open to facilitate smooth substrate transfer, and each of the chambers C1 to C3 is maintained in a sealed environment from the outside by a ceiling wall, thereby preventing liquid generated in these units C1 to C3 from floating out in the form of droplets. A partition 55 equipped with a shutter that opens or closes the passage by reciprocating movement (55d) is provided between the brush cleaning chamber C2 and the drying chamber C4 to prevent the liquid droplets generated from the brush cleaning unit 320 from flowing into the drying unit 340 and reattaching the liquid droplets to the surface of the substrate G. Meanwhile, the rinsing chamber C3 may be omitted, and in this case, the partition 55 equipped with a shutter is disposed between the brush cleaning chamber C2 and the drying chamber C4. That is, it is preferable to install the partition 55 equipped with the shutter that restricts the flow of liquid droplets between the unit that performs processes such as cleaning and rinsing with liquid and the drying chamber C4.

The cleaning unit CLN not only cleans and dries the substrate G by transferring the substrate G through a plurality of cleaning chambers after the polishing process for the first surface of the substrate G is completed (S4), but also cleans and dries the substrate G by transferring the substrate G through a plurality of cleaning chambers after the polishing process for the second surface of the substrate G is completed (S9).

The unloading unit UL is disposed to continue from an end of the cleaning unit CLN so that the substrate G is continuously transferred by the transfer roller 390 of the cleaning unit CLN and receives the substrate G on which the cleaning process in the cleaning unit CLN is completed through the transfer roller 390. In addition, the substrate G is transferred to the substrate supply path 88 or the substrate discharge unit CPe by the substrate supply handler IR (S6 and S11).

That is, after the first surface of the substrate G is polished, the substrate G that has been subjected to the cleaning process in the cleaning unit CLN is re-supplied from the unloading unit Ul to the substrate supply path 88 and transferred to the preliminary cleaning unit PC or the second processing apparatus 102 by the substrate transfer handler TR. In addition, after the second surface of the substrate G is polished in the second processing apparatus 102, the substrate G that has been subjected to the cleaning process in the cleaning unit CLN is transferred from the unloading unit UL to the substrate supply unit Cpe and transferred to a device in which an external subsequent process is performed through the substrate supply unit CPi.

Meanwhile, a first surface polishing process in the first processing apparatus 101 for the substrate G and a second surface polishing process in the second processing apparatus 102 for the substrate G may be completed in one step, but the present invention is not limited thereto, and the polishing process may be repeatedly performed on the first surface and the second surface in the first processing apparatus and the second processing apparatus, respectively. For example, when the substrate G is supplied from the substrate supply unit Cpi to the alignment unit AL of the substrate supply path 88 by the substrate supply handler IR (S0 and S1), the substrate G is supplied to the first processing apparatus 101 by the substrate transfer handler TR (S2) to perform a polishing process on the first surface, the substrate G on which the polishing process is performed on the first surface by the substrate transfer handler TR is transferred to the cleaning unit CLN (S3), the cleaning and drying process is performed in the cleaning unit including the plurality of cleaning chambers (S4), and when the substrate G reaches the unloading unit UL, the substrate G is re-supplied to the alignment unit AL of the substrate supply path 88 by the substrate supply handler IR (S6), and supplied to the first processing apparatus 101 through the substrate transfer handler TR (S2) so that the second polishing process may be performed on the first surface. In this way, the polishing process may be performed on the first surface as many times as necessary. Similarly, in the second processing apparatus 102, the polishing process may be performed on the second surface of the substrate G as many times as necessary until a target thickness reaches.

Further, even when the components of the first processing apparatus 101 and the second processing apparatus 102 are configured and arranged identically or similarly, the components may be operated to have a difference in the polishing process by making a difference in the type of slurry used in each of the processing apparatuses 101 and 102 or a rotation speed of the polishing pad, etc., thereby making the polishing conditions of the first surface and the second surface of the substrate G different.

As described above, in the substrate processing apparatus 1 according to the present invention, the first processing apparatus 101 and the second processing apparatus 102 for performing the first polishing process and the second polishing process for the large-area substrate are disposed on one side of the substrate supply path 88 that extends in the forward and backward direction, the preliminary cleaning unit PC is disposed on the other side of the end of the substrate supply path 88, the cleaning unit CLN formed with a plurality of chambers C1 to C5 is disposed along the substrate supply path 88 from the preliminary cleaning unit PC, the unloading unit UL is disposed to be continuous from the cleaning unit CLN, the processing apparatus 100 (101 and 102), the substrate supply path 88, the cleaning unit 320, and the unloading unit 400 are disposed in a dense rectangular shape, and thus an installation area (foot print area) 77 of these units is minimized, thereby obtaining an advantageous effect of increasing the space utilization of the factory.

Further, after the first surface of the substrate G is polished in the first processing apparatus 101, and after foreign substances such as sludge attached to the first surface are completely removed through the cleaning process in the cleaning unit CLN, the substrate G may be transferred to the second processing apparatus 102 and performing the polishing process may be performed on the second surface, and thus the problem affecting non-uniformity of the polished surface on the second surface, which would have been caused by the presence of sludge on the first surface, may be fundamentally resolved, thereby obtaining an advantageous effect of improving the polishing quality of the second surface.

In addition, during the process of supplying the substrate G to the determined process position PP of the polishing pad in each of the processing apparatuses 101 and 102, by supplying the substrate G after the position of the substrate G is corrected to be accurately aligned to the process position using a camera or sensor, the substrate G is accurately accommodated in the quadrangular-shaped accommodating through opening 123x of the polishing head, and thus the effect of preventing damage to the corner portion of the substrate, which is vulnerable to an external force, during the polishing process may be obtained.

Meanwhile, according to a second embodiment of the present invention, as illustrated in FIG. 9, in a substrate processing apparatus 2, a first processing apparatus 201 and a second processing apparatus 202 are formed differently from each other. That is, the first processing apparatus 201 may be formed to be identical or similar to the first processing apparatus 101 of the embodiment described above, and the second processing apparatus 202 may be formed differently from the first processing apparatus 101 in order to polish a material having a higher hardness.

That is, the first processing apparatus 201 may be used to polish a glass material of a glass substrate or to polish a material (e.g., a copper layer) having a relatively low hardness. In addition, the second processing apparatus 202 may be used to polish a material (e.g., a titanium layer) having a higher hardness.

In order to polish a material having a higher hardness, as illustrated in FIG. 9, a substrate G is supplied to a predetermined process position of a substrate chuck 210 by a substrate transfer handler TR. Then, the substrate chuck 210 adsorbs a lower surface of the substrate G to fix the substrate G to a chuck surface so that the substrate G is firmly fixed without shaking.

Similar to the first embodiment described above, a position and attitude of the substrate transfer handler TR are corrected by a substrate position detection unit so that the substrate G is seated at a predetermined process position PP of the substrate chuck 210 by the substrate position detection unit. Thereafter, the substrate G is seated on the substrate chuck 210.

Thereafter, a grinder wheel 230 moves (230d) to a position above the substrate chuck 210, and the grinder wheel 230 rotates to grind a surface of the substrate G. The grinder wheel 230 may be formed in the shape of a thick disc to grind the surface of the substrate G in a circumferential curved shape or may grind the surface of the substrate G in a flat shape. Although not illustrated in the drawing, a slurry or abrasive, etc., may be supplied to the polished surface.

The grinder wheel 230 is suitable for grinding a material having a higher hardness than a polishing pad, and thus the grinder wheel 230 is suitable for grinding a layer made of a material such as titanium having a high hardness. However, the present invention is not limited thereto, and the second processing apparatus 202 may be formed identically or similarly to the first processing apparatus 201, and the polishing pad of the second processing apparatus 202 may be selected to have a higher hardness than the polishing pad of the first polishing device 201 to polish the material to be polished.

Hereinafter, the operating principle of the substrate processing apparatus 2 configured as above will be described.

First, when one of substrates G loaded in a substrate supply unit Cpi is supplied to an alignment unit AL of a substrate supply path 88 through a substrate supply handler IR (S0), a substrate transfer handler TR that moves back and forth along the substrate supply path 88 approaches the alignment unit AL, and the substrate transfer handler TR picks up the substrate G from the alignment unit AL (S1).

In addition, the substrate transfer handler TR moves along the substrate supply path 88 while gripping the substrate G (90d) and stops at a predetermined position to supply the substrate G to the first processing apparatus 201. Thereafter, the substrate transfer handler TR supplies the substrate G to the first processing apparatus 201 so that a first surface of the substrate G comes into contact with a polishing pad 111 (S2). In addition, a copper layer or glass layer of the first surface of the substrate G is polished in the first processing apparatus 201.

When the polishing process for the first surface of the substrate G is completed, the substrate transfer handler TR grips the substrate from the first processing apparatus 201 and transfers the substrate G to a preliminary cleaning unit PC. In addition, at a time appropriate for providing the substrate G to the second processing apparatus 202 in consideration of a cleaning time in a cleaning unit CLN, the substrate transfer handler TR grips the substrate G from the preliminary cleaning unit PC and transfers the substrate G to the cleaning unit CLN (S3). As necessary, after a preliminary cleaning process is performed on the substrate G in the preliminary cleaning unit PC, the substrate G may be flipped 180 degrees immediately and moved back to the first processing apparatus 201 for polishing a second surface of the substrate G.

The substrate G moved to the cleaning unit CLN is subjected to a cleaning and drying process while passing through a plurality of cleaning chambers C1 to C5. The substrate G that has been subjected to the cleaning and drying process reaches an unloading unit UL, and the substrate G seated in the unloading unit UL is moved back to the alignment unit AL by the substrate supply handler IR. Then, the substrate transfer handler TR grips the substrate G of the alignment unit AL and moves the substrate G to the first processing apparatus 201 in a 180-degree flipped state. Thereafter, a copper layer or glass layer of the second surface of the substrate G is polished.

As necessary, the polishing process for each of the first surface and the second surface of the substrate G may be completed one time, but when it is necessary to repeat the polishing process multiple times, after each polishing process is performed, and after the cleaning process in the preliminary cleaning unit PC or cleaning unit CLN is performed, it is then provided back into the first processing apparatus 201 to perform the polishing process for the first surface or the polishing process for the second surface as many times as necessary.

Through this, all the polishing processes for the copper layers of the first surface and the second surface of the substrate G are completed.

Next, after passing through the cleaning unit CLN, the substrate G is transferred back from the unloading unit UL to the substrate supply handler IR (S5) and then transferred to the alignment unit AL of the substrate supply path 88 (S6). Then, the substrate transfer handler TR grips the substrate G from the alignment unit AL and supplies the substrate G to the second processing apparatus 202 (S7).

Then, in the second processing apparatus 202, the substrate G is seated at a predetermined process position of the substrate chuck 210, and the grinder wheel 230 grinds the first surface of the large-area substrate G for a predetermined period of time, thereby polishing a titanium layer of the substrate G, which has a high hardness. During the polishing process, a slurry, a coolant, an abrasive, etc. may be supplied together.

When a polishing process for the titanium layer of the first surface of the substrate G is completed, the substrate G is transferred back to the cleaning unit CLN by the substrate transfer handler TR (S8). In addition, a cleaning and drying process is performed on the first surface of the substrate G while passing through a plurality of cleaning chambers C1 to C5 (S9), and then after passing through the unloading unit UL, the substrate supply handler IR, and the alignment unit AL (S10 and S6), the substrate G gripped by the substrate transfer handler TR is supplied to the second processing apparatus 202 in a state flipped 180 degrees (S7).

In addition, in the second processing apparatus 202, a polishing process is performed on the titanium layer of the second surface of the substrate G by the grinder wheel 230. Similarly, when the polishing process for the titanium layer of the first surface of the substrate G is completed, the substrate G is transferred back to the cleaning unit CLN by the substrate transfer handler TR (S8). In addition, a cleaning and drying process is performed on the second surface of the substrate G while passing through the plurality of cleaning chambers C1 to C5 (S9), and the substrate G is transferred back to the unloading unit UL.

The polishing process may be performed on a titanium layer having a high hardness of each of the first surface and the second surface one time. As necessary, the polishing process may need to be performed on each of the first surface and the second surface having the titanium layer multiple times. In this case, the polishing process may be performed on the first surface and the second surface multiple times while repeating the processes of S6 to S10.

Through this, the copper layer and the titanium layer of the substrate G are each polished one time or multiple times in the processing apparatuses 201 and 202 having different polishing characteristics, thereby making it possible to polish layers having different hardnesses from the substrate G in a single apparatus.

As described above, according to the present invention, by performing double side polishing on a large-area substrate used in a display device, a variation in the polished surface between both surfaces of the substrate can be minimized and a polishing process can be performed more precisely and flatly, thereby obtaining an advantageous effect of providing a substrate for a display device used in a display device with higher resolution.

In addition, according to the present invention, by capturing the position of a quadrangular-shaped substrate using vision before placing the substrate on a circular polishing pad, correcting the placement position of the substrate in a substrate transfer handler, and then placing the substrate on a polishing pad, the placement position of the substrate is made accurate, and through this, the substrate can be accurately seated on a retainer of a polishing head, thereby obtaining an advantageous effect of ensuring the accuracy of the process.

Above all, according to the present invention, by arranging a first processing apparatus for polishing a first surface of a substrate and a second processing apparatus for polishing a second surface of the substrate side by side with respect to a substrate supply path and arranging a cleaning unit including a plurality of cleaning units for a sequential cleaning process in a line to face them, it is possible to obtain an advantageous effect of minimizing a footprint area occupied by a substrate processing apparatus for performing polishing and cleaning processes on a large-area substrate into a rectangular shape.

Further, according to the present invention, by performing a polishing process on an entire surface of a quadrangular-shaped flat substrate with a side length of 500 mm or more in contact with a polishing pad, a variation in the polishing amount according to the position of the substrate can be minimized, thereby obtaining an advantageous effect of improving polishing quality.

In addition, according to the present invention, after a polishing process is performed on the first surface of the substrate, by cleaning the first surface of the substrate through a cleaning process to remove foreign substances remaining on the substrate, thereby obtaining an advantageous effect of preventing sludge remaining on the first surface from adhering and degrading the quality of the polished surface of the substrate while the polishing process is performed on the second surface of the substrate.

In addition, according to the present invention, by positioning a large-area quadrangular-shaped substrate in a predetermined position and attitude on a turntable equipped with a polishing pad and positioning the substrate below a polishing head that presses the polishing pad downward, it is possible to obtain an advantageous effect of increasing the reliability of the polishing process by preventing damage to the substrate through restricting excessive load or unreasonable movement on the substrate during the process of pressing the substrate by the polishing head.

While exemplary embodiments of the present invention have been described above, it should be understood by those skilled in the art that various modifications and changes may be made herein without departing from the spirit and scope of the present invention as defined by the following claims.

What is claimed is:

1. A substrate polishing apparatus comprising:
a turntable which has an upper surface, on which a polishing pad is disposed, and rotates during a polishing process;
a substrate transfer handler configured to supply a substrate onto the upper surface of the turntable;
a substrate position detection unit configured to detect a position of the substrate when the substrate transfer handler causes the substrate to be positioned above a target seating portion of the polishing pad; and
a polishing head configured such that a position of the substrate transfer handler is corrected so that the position of the substrate detected by the substrate position detection unit is a predetermined process position, the substrate transfer handler causes the substrate to be seated at the predetermined process position of the polishing pad, then moves to a position above the substrate seated on the polishing pad, and presses the substrate downward during the polishing process for the substrate.

2. The substrate polishing apparatus of claim 1, wherein the substrate position detection unit includes one or more of a camera positioned above the turntable to detect the position of the substrate, a laser displacement sensor which detects an edge of the substrate, and a line scan camera.

3. The substrate polishing apparatus of claim 1, wherein the substrate transfer handler is rotatable 180 degrees so as to allow the substrate to flip.

4. The substrate polishing apparatus of claim 1, wherein the polishing head is installed to be reciprocally movable between an upper position above the process position and a retracted position spaced apart from the upper position.

5. The substrate polishing apparatus of claim 4, wherein, in a state in which the polishing head is moved to the retracted position, the substrate transfer handler places the substrate on the polishing pad at the process position.

6. The substrate polishing apparatus of claim 4, further comprising:
a moving rail which connects the upper position and the retracted position; and
a driving unit which reciprocates the polishing head along the moving rail.

7. The substrate polishing apparatus of claim 6, wherein, during the polishing process for the substrate, the polishing head performs an oscillation motion that reciprocates a predetermined distance at a predetermined period, and the oscillation motion is performed by the driving unit, which causes the polishing head to reciprocate along the moving rail.

8. The substrate polishing apparatus of claim 1, further comprising substrate displacement detection sensors which are positioned at a plurality of positions around a periphery of the polishing head and detect a displacement of the substrate.

9. A substrate processing apparatus, in which a polishing process is performed on a substrate, comprising:
a substrate supply unit configured to supply a substrate on which a polishing process is to be performed;
a substrate transfer handler on which the substrate supplied from the substrate supply unit is seated and which reciprocates along a substrate supply path disposed along a linear shape to supply the substrate;
a substrate supply handler configured to supply the substrate from the substrate supply unit along the substrate supply path;
a first processing apparatus which is disposed adjacent to the substrate supply path and performs a first processing process on the substrate supplied from the substrate transfer handler; and
a second processing apparatus which is disposed adjacent to the substrate supply path together with the first processing apparatus and performs a second processing process on the substrate on which the first processing process has been performed.

10. The substrate processing apparatus of claim 9, further comprising an alignment unit configured to align a position and attitude of the substrate at a position of one end portion of the substrate supply path along which the substrate is supplied by the substrate transfer handler,
wherein the substrate supplied by the substrate transfer handler is in an aligned state.

11. The substrate processing apparatus of claim 9, wherein the first processing process is a polishing process for a first surface of the substrate, and the second processing process is a polishing process for a second surface of the substrate.

12. The substrate processing apparatus of claim 11, wherein the substrate transfer handler flips the substrate having the first surface, on which the polishing process is performed in the first processing apparatus, and supplies the flipped substrate to the second processing apparatus.

13. The substrate processing apparatus of claim 11, further comprising a preliminary cleaning chamber positioned at the other end portion of the substrate supply path, which cleans the substrate having the first surface on which the polishing process is performed by spraying a non-contact high-pressure cleaning solution,
wherein, in a process in which the substrate transfer handler moves the substrate from the first processing apparatus to the second processing apparatus after the polishing process for the first surface is completed, the substrate is positioned in the preliminary cleaning chamber to perform preliminary cleaning on the first surface.

14. The substrate processing apparatus of claim 11, wherein, after the polishing process is performed on the first surface and the second surface of the substrate, a cleaning unit including a plurality of cleaning chambers for cleaning the substrate is arranged to face the first processing apparatus and the second processing apparatus along the substrate supply path.

15. The substrate processing apparatus of claim 9, wherein the first processing process is a polishing process for polishing a copper layer of the substrate, and the second processing process is a polishing process for polishing a titanium layer of the substrate.

16. The substrate processing apparatus of claim 15, wherein a cleaning unit including a plurality of cleaning chambers for cleaning the substrate is arranged to face the first processing apparatus and the second processing apparatus along substrate supply path.

17. The substrate processing apparatus of claim 16, wherein the cleaning unit includes:
a rinsing chamber in which a rinsing solution is sprayed onto the substrate to rinse the substrate;
a brush chamber in which the substrate is cleaned while rotating a brush relative to the substrate; and
a drying chamber in which the substrate is dried.

18. The substrate processing apparatus of claim 16, wherein a copper polishing process is performed on the first surface of the substrate in the first processing apparatus, then the substrate transfer handler moves the substrate to the cleaning unit, and a cleaning process is performed on the first surface in the cleaning unit;
then, a copper polishing process is performed on the second surface of the substrate in the first processing apparatus, then the substrate transfer handler moves the substrate to the cleaning unit, and a cleaning process is performed on the first surface in the cleaning unit;
then, a titanium polishing process is performed on any one of the first surface and the second surface of the substrate in the second processing apparatus, then the substrate transfer handler moves the substrate to the cleaning unit, and a cleaning process is performed on the surface, on which the titanium polishing process has been performed in the second processing apparatus, in the cleaning unit; and
then, a titanium polishing process is performed on the other of the first surface and the second surface of the substrate in the second processing apparatus, then the substrate transfer handler moves the substrate to the cleaning unit, and a cleaning process is performed on the surface, on which the titanium polishing process has been performed in the second processing apparatus, in the cleaning unit.

19. The substrate processing apparatus of claim 18, wherein the copper polishing process is repeated on the first surface and the second surface two or more times, and after the copper polishing process is completed, the titanium polishing process is performed on the first surface and the second surface.

20. The substrate processing apparatus of claim 18, wherein the second processing apparatus includes:
a substrate chuck which fixes the substrate supplied from the substrate transfer handler; and
a grinder wheel which grinds an upper surface of the substrate fixed to the substrate chuck.
